(19) United States
(12) Patent Application Publication
(10) Pub. No.: US 2026/0164679 A1
(43) Pub. Date: Jun. 11, 2026

(54) UNDERHUNG CACHE STACKED CHIPLET ON GLASS CORE

(71) Applicant: Intel Corporation, Santa Clara, CA (US)

(72) Inventors: Jiun Hann Sir, Gelugor (MY); Eng Huat Goh, Ayer Itam (MY); Telesphor Kamgaing, Chandler, AZ (US); Chan Kim Lee, Penang (MY)

(73) Assignee: Intel Corporation, Santa Clara, CA (US)

(21) Appl. No.: 18/969,932

(22) Filed: Dec. 5, 2024

(51) Int. Cl. H10B 80/00; H01L 23/00; H01L 23/13; H01L 23/15; H01L 23/538; H01L 25/00; H01L 25/18

(52) U.S. Cl. CPC H10B 80/00; H10W 70/611; H10W 70/635; H10W 90/00; H10W 70/68; H10W 70/692; H10W 72/01255; H10W 90/724; H10W 90/792

(57) ABSTRACT

An underhung cache chiplet architecture creating a three-dimensional L3 cache. Examples stack a cache die on a cache in a system die and hybrid bond (HB) them together, creating a “T” shaped assembly that is attached a glass core interposer via solder micro-bump fields. The coefficient of thermal expansion (CTE) of the glass core interposer can be tailored in an application specific approach.

### BACKGROUND

It is well known that large caches can provide significant performance gains to semiconductor systems and packages. Yet, the scaling of monolithic static random-access memory (SRAM) has not kept pace with the scaling of other standard cell logic components. Because some chiplets can contain over 50% SRAM by area, improvements to SRAM density and integration with logic are desirable.

### BRIEF DESCRIPTION OF THE DRAWINGS

FIG. 1A is a comparison table showing various cache architectures.

FIG. 1B is a simplified cross-sectional illustration of hybrid bonding in the underhung cache chiplet, in accordance with various embodiments described herein.

FIG. 2 is a simplified cross-sectional illustration of the underhung cache chiplet architecture in a semiconductor system, in accordance with various embodiments.

FIG. 3 depicts various stages of fabrication of the underhung cache chiplet architecture, in accordance with various embodiments.

FIGS. 4-5 depict various stages of fabrication of the glass core and organic substrate for the underhung cache chiplet architecture, in accordance with various embodiments.

FIG. 6 depicts various assembly stages for implementing the underhung cache architecture, in accordance with various embodiments.

FIG. 7 illustrates an example method for the underhung cache architecture, in accordance with various embodiments.

FIG. 8 illustrates an example method for the glass core substrate architecture, in accordance with various embodiments.

FIG. 9 is a top view of a wafer and dies that may be included in a microelectronic assembly, in accordance with any of the embodiments disclosed herein.

FIG. 10 s a simplified cross-sectional side view showing an implementation of an integrated circuit on a die that may be included in various embodiments, in accordance with any of the embodiments disclosed herein.

FIG. 11 is a cross-sectional side view of a microelectronic assembly that may include any of the embodiments disclosed herein.

FIG. 12 is a block diagram of an example electrical device that may include any of the embodiments disclosed herein.

### DETAILED DESCRIPTION

It is well known that large caches can provide significant performance gains to semiconductor systems and devices. Yet, the scaling of monolithic static random-access memory (SRAM) has not kept pace with the scaling of other standard cell logic components. Some chiplets can contain over 50% SRAM by area. Large two-dimensional (2D) cache architectures mean a larger chip/die, and since the yield of a chip/die is somewhat proportional to its size, the large 2D cache can lower the yield, which can increase the wafer/chip cost. Additionally, making the L3 cache bigger in two dimensions means the distance across the cache is bigger, which increases the latency of the cache and therefore can actually hinder the performance gains out of the compute engine.

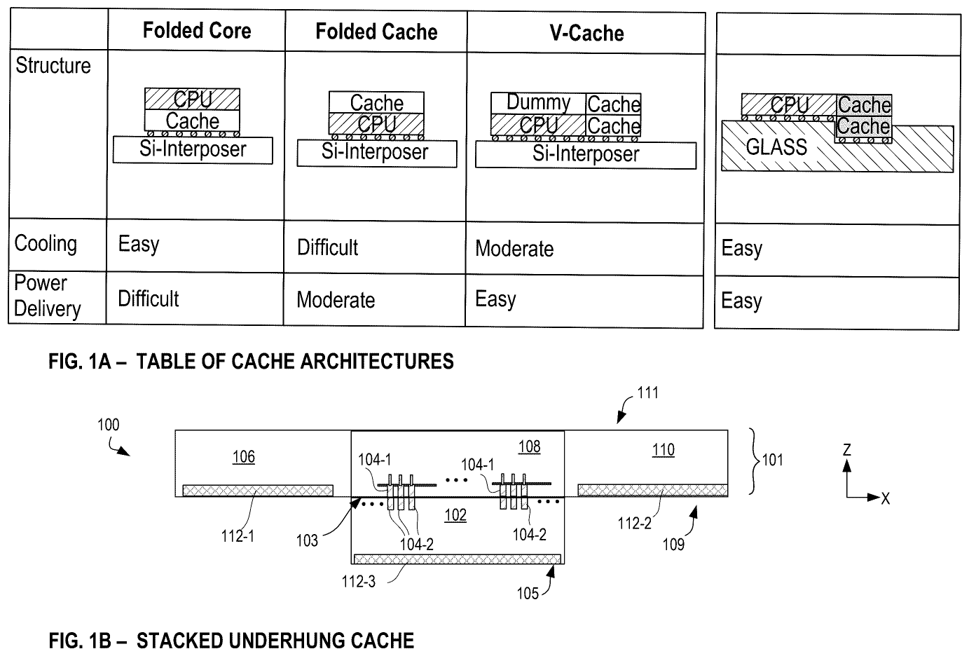

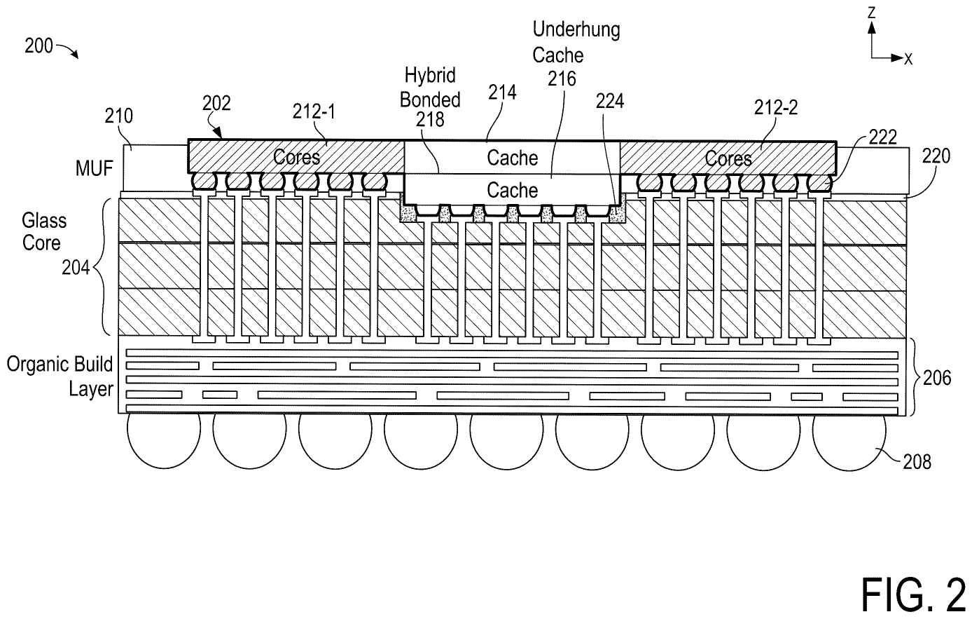

Some die stacking solutions have been introduced to address the above-described technical problems, but each available die stacking solution has an associated compromise, not limited to a tradeoff between power delivery and cooling, as illustrated and discussed with respect to the table in FIG. 1A.

Embodiments described herein provide a technical solution to these technical challenges in the form of an underhung cache chiplet architecture. The embodiments stack cache die and employ hybrid bonding (HB), also referred to as hybrid bonding interconnect (HBI) or direct bond interconnect (DBI). HBI is a packaging technology that involves bringing together the surfaces of two semiconductor devices under applied pressure and/or at elevated temperature, generally as a die stacking solution, resulting in dielectric-to-dielectric bonding and metal-to-metal bonding. HBI advantageously enables “small” pitches (defined herein as a pitch less than 10 microns +/−10%, and in some cases, the pitch is less than 1 micron +/−10%). Embodiments of the underhung cache chiplets are fabricated to attach to a glass core interposer via solder micro-bump fields. The coefficient of thermal expansion (CTE) of the glass core interposer/substrate can be tailored in an application specific approach. These concepts are developed in more detail below.

Example embodiments are hereinafter described in conjunction with the following drawing figures, wherein like numerals denote like elements. Unless otherwise stated, figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

FIG. 1A provides a comparison of architectures for including a larger L3 cache in a multi-die assembly or system. A folded core architecture places the CPU die on the cache die, and the cache die is attached to a silicon interposer. This folded core architecture makes cooling the CPU easy, but delivery of power through the silicon interposer to the cache and CPU is difficult. The folded cache architecture places the cache die on the CPU die, and the CPU die is attached to a silicon interposer. This folded cache architecture makes cooling the CPU a difficult task due to it being covered by the cache, but delivery of power through the silicon interposer to the cache and CPU is moderately challenging. A V-cache architecture attaches the CPU die and a cache die side by side on a silicon interposer, and then puts another cache die on top of the cache die, and a dummy die on top of the CPU die, to achieve a consistent upper surface. This V-cache architecture makes it a little easier, moderately difficult to cool the CPU, but delivery of power through the silicon interposer to the cache and CPU is easier than the first two architectures described.

Embodiments of the underhung cache architecture, in the right-most column, are distinguishable from the first three embodiments in several ways. First, the total amount of system cache is divided among two dies, with a cache die stacked and hybrid bonded on the cache in the system die. Additionally, embodiments are implemented with a glass core interposer/substrate; the glass core interposer/substrate has a cavity formed in its upper surface to accommodate or partially enclose the stacked cache die. The core or CPU of the system die is external to and adjacent to the stacked cache. Embodiments make the CPU easy to cool because it is exposed, and delivery of power through the glass core interposer to the cache and CPU is easy. Embodiments are a three-dimensional cache, via cache stacking, and advantageously deliver lower memory latency. In the following discussion, embodiments of the underhung cache architecture are described in more detail.

Turning to FIG. 1B, the underhung cache chiplet architecture, also referred to as the underhung cache architecture 100 includes a system die 101 and the underhung cache 102 die (the underhung cache 102 is sometimes referred to as the stacked cache). The exemplary system die 101 comprises a first core 106, a second core 110, and a first cache 108 sandwiched between the first core 106 and the second core 110 in the XY plane (in other words, as illustrated, they are not stacked in the Z direction, but positioned side by side from left to right in the X direction in FIG. 1B). This is a non-limiting example, in other embodiments, there may be just one core, more than two cores, one or more cores, etc.

The core 106 and the core 110, may be unpackaged integrated circuit die, and may alternatively be referred to as chips, chiplets, chip complexes, or chiplet complexes. While the terms die, chip, and chiplet may be used interchangeably, the term chiplet is sometimes used to refer to an integrated circuit die that implements a subset of the functionality of a larger integrated circuit component. The chiplets may vary by type/functionality (e.g., compute, memory, I/O, power management (i.e., controlling the delivery of power and/or providing power to components)).

The underhung cache architecture 100 has a first surface 111 (shown as the upper surface in the figure) and a second surface 109 (shown as the bottom surface in the figure). Electronic communication between core 106, core 110, cache 108, and cache 102 is facilitated through electronic pathways in the respective components.

In various embodiments, the means for attachment between the cache 108 and stacked or underhung cache 102 can be hybrid bonding (HB), first level interconnect thermal compression bonding (TCB) micro ball, or plating.

In some embodiments, the underhung cache 102 is hybrid bonded (HB) along a HB interface 103 shared between the two cache dies. The HB interface 103 includes a region of the second surface 109 (corresponding to the cache 108 on the system die 101) with insulating material with a plurality of HB contacts 104-1 therein, and another matching region of insulating material with another plurality of HB contacts 104-2 in the stacked cache die 102. At the HB interface 103, the HB contacts 104-1/104-2 are exposed on their respective surfaces, and the dielectric is also exposed; in other words, at the HB interface, respective surfaces have dielectric material adjacent to metal/Cu hybrid bond contacts.

The HB contacts 104-1 and HB contacts 104-2 may be a metal and may comprise copper. In various embodiments, at least one hybrid bond contact 104-1 and at least one hybrid bond contact 104-2 is exposed at the HB interface 103.

The insulating material may be any dielectric material, such as, a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, a dielectric layer comprises a photo-imageable dielectric (PID). In some embodiments, the dielectric layer comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)). In other embodiments, the dielectric material can be any type of epoxy molding compound.

Accordingly, at the HB interface 103, insulating or dielectric material of cache 108 and insulating or dielectric material of cache 102 are bonded together (e.g., in a SEM image, one would see the dielectric material SiOx to SiOx, SiOxNy to SiOxNy, or the like) and HB contacts 104-1 are bonded to HB contacts 104-2. There is no solder material at the HB interface 103.

In some embodiments, HBI contacts can be 10 microns, in other embodiments, the HB contacts can be 2 microns. The HBI pitch may be less than 25 microns. In a non-limiting example, the HB pitch is in a range of 1 to 10 microns, inclusive.

Embodiments form a “T” shaped assembly that is attached a glass core interposer via solder micro-bump fields. At the second surface 109 and external to the cache(s), the first core 106 and the second core 110 include a respective field of micro-bump conductive contacts, as illustrated generally with hatched region 112-1 and 112-2. Additionally, the surface 105 of the underhung cache die 102 includes a field of micro-bump conductive contacts, as illustrated generally with hatched region 112-3.

The pitch of the micro-bumps is larger than the pitch of the hybrid bond interconnect (HBI) contacts. The micro bump fields corresponding to hatched regions 112-1, 112-2, and 112-3 may have a solder bump pitch (BP) in a range of 25 microns to 55 microns plus or minus 10% (often referred to as “fine pitch”). In some scenarios, the fine pitch BP can be 10 microns +/−10%. Alternatively, the BP may be “coarse pitch,” which refers to a pitch ≥90 microns plus or minus 10%.

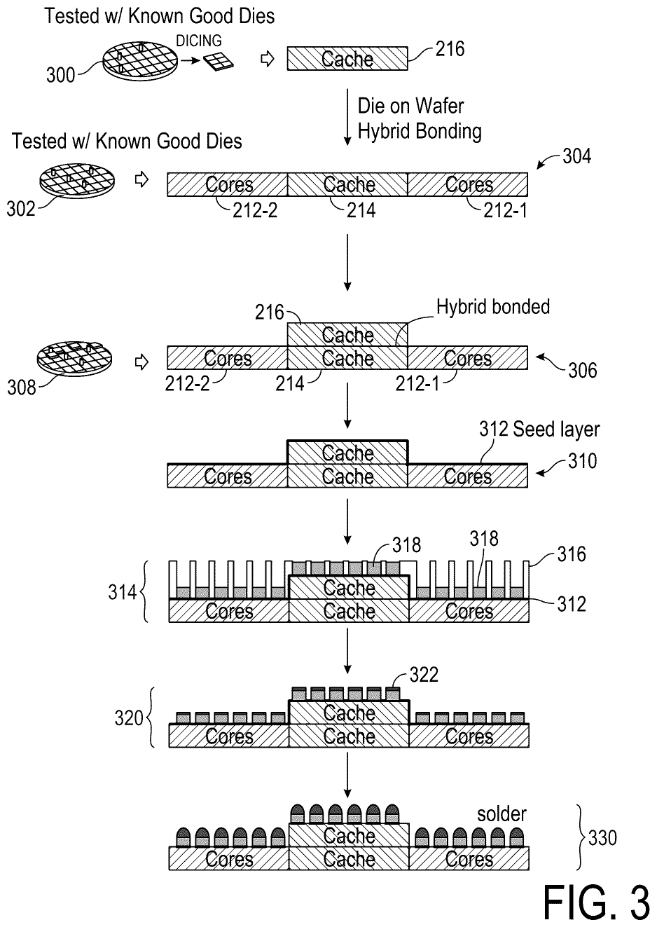

FIG. 2 is a simplified cross-sectional illustration of an underhung cache assembly 200 (sometimes simplified to “cache assembly” hereinbelow) comprising the underhung cache architecture 100/202 attached to the upper surface of a glass core 204. The cache assembly 200 also has an organic build layer 206 on the lower surface of the glass core 204, and solder bumps 208 on the lower surface of the organic build layer 206. A mold/underfill (MUF 210) material surrounds the underhung cache architecture 100/202 on the upper surface of the glass core 204.

A dielectric layer 220 may be overlaid on the upper surface of the glass core 204. An underfill 210 material may surround the underhung cache 216 in the cavity.

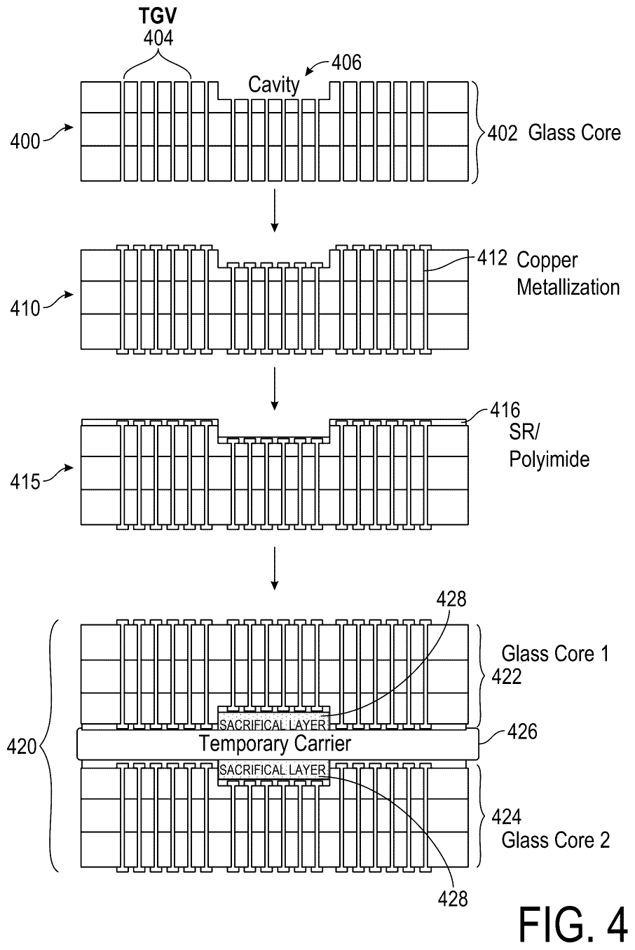

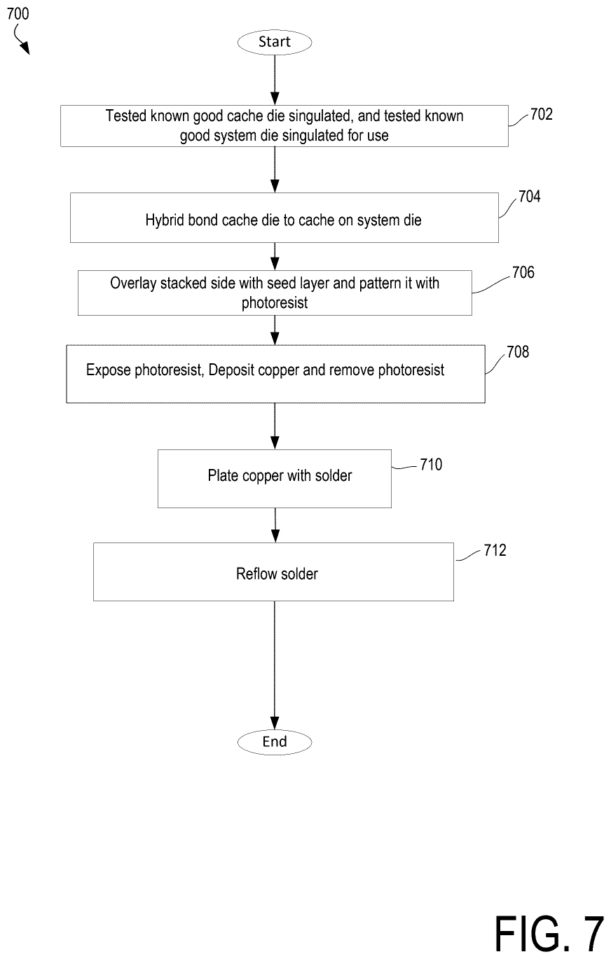

FIG. 3 depicts various stages of fabrication of the underhung cache architecture 202, and FIG. 7 illustrates a method 700 for fabricating the underhung architecture 202. At 702, a wafer 300 comprising cache dies is tested and individual known good cache dies are diced to become an eventual stacked cache 216 die. Also at 702, a wafer 302 of system dies 101/304 is tested and a known good system die 101/304 is selected.

At 704 the stacked cache 216 die is hybrid bonded on the cache 214 of the system die 304, creating the embodiment 306. At 706, a seed layer 312 is overlaid on the embodiment 306 to thereby create embodiment 310. Also at 706, photoresist 316 is patterned on the seed layer 312, creating embodiment 314.

At 708, the photoresist is exposed and then copper is deposited, and photoresist is removed, creating embodiment 320, with copper bumps. The photoresist is stripped, and the seed layer is removed in an etch process. Embodiment 320 also illustrates, at 710, the copper bumps are plated with solder. At 712, the copper and solder bumps are exposed to heat to cause the solder to reflow, creating embodiment 330, which is analogous to the underhung cache architecture 202.

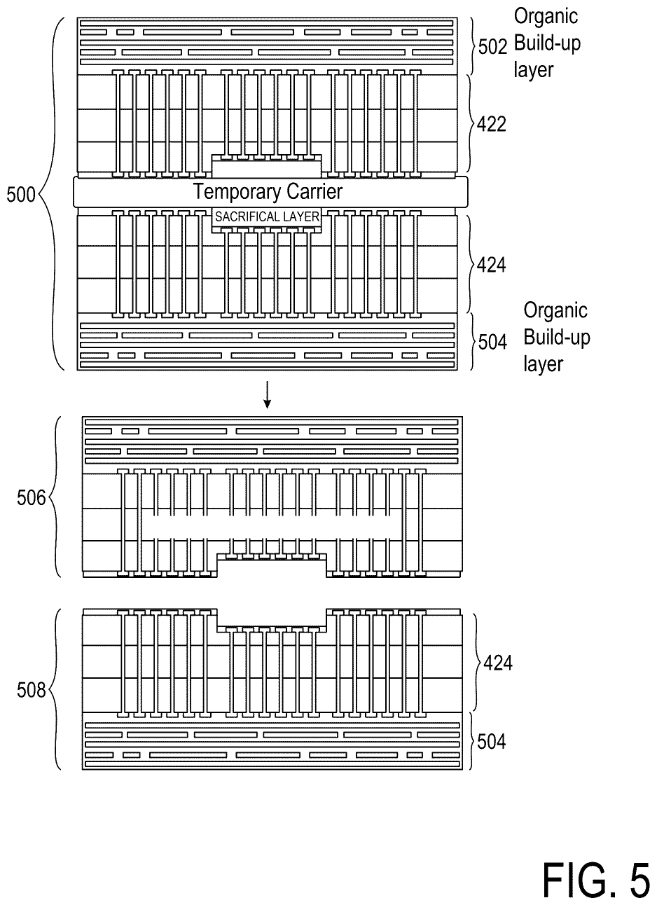

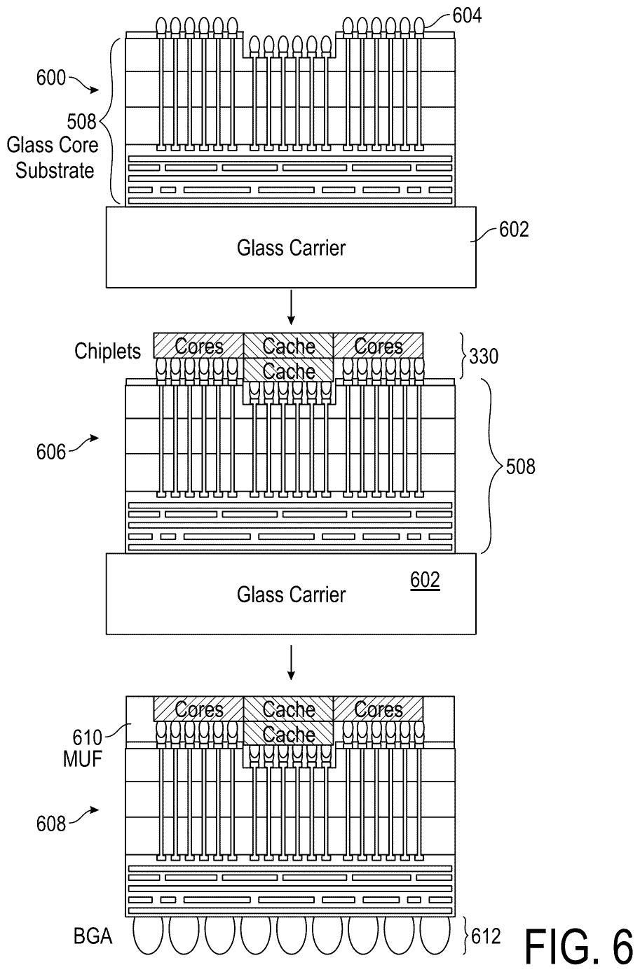

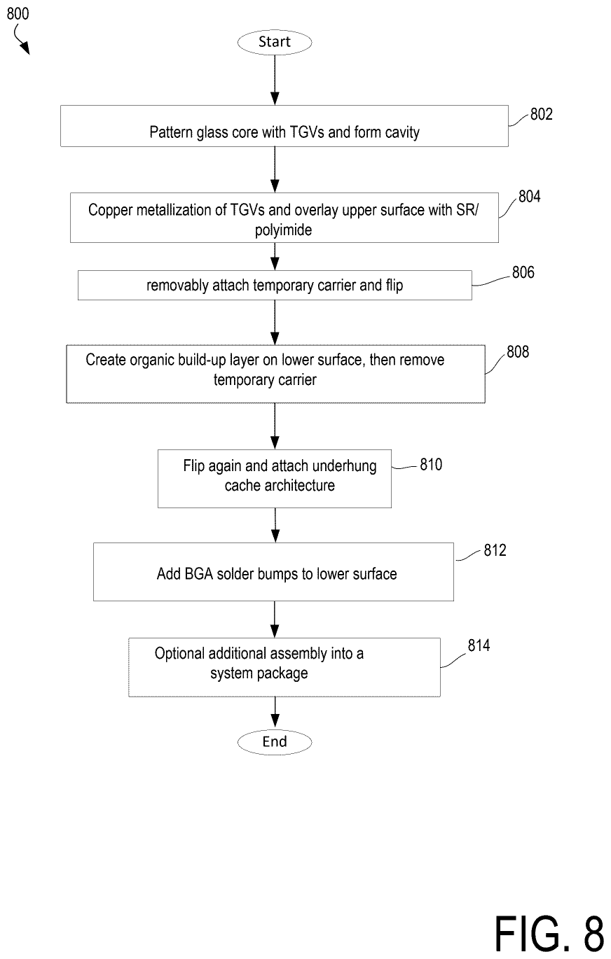

FIGS. 4-5 depict various stages of fabrication of the glass core 204/402 and organic substrate or build layer 206 for the underhung cache assembly 200, FIG. 6 depicts attaching the underhung cache architecture 202 to the glass interposer/substrate, and FIG. 8 illustrates a method 800 for fabricating the glass core 204/402, attaching the underhung cache architecture 202, and creating a final product.

At 802, a layer of glass to become the glass core 204/402 is patterned with TGVs 404 and the cavity 406 is formed therein. The glass core 204/402 may comprise a layer of glass, (as used herein, glass can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO2, Al2O3, B2O3, and MgO)), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles, such as gold, silver, or other suitable metallic particles. The glass core 204/402 may have a CTE in a range of 2-20 ppm/K. In some embodiments, it is advantageous for the layer of glass 402 to have a CTE that matches that of the intended core dies 106 and 110 in the assembled product. In various embodiments, the core dies 106 and 110 are integrated circuit dies (e.g., match the CTE of silicon) or to have a CTE that matches a substrate or PCB.

In some embodiments, the glass core 204/402 may comprise multiple glass sheets bonded together with an adhesion layer; and may further exhibit a CTE gradient along the Z axis. In various embodiments, e.g., in a glass substrate or embodiment 400 with a Z height (in the drawing) in a range of about ≤1 millimeters (mm) to 5 mm, the layer of glass 402 or glass core may have a thickness (Z height) in a range of about 50 +/−5 microns to about 1.5 millimeter, +/−10%. The TGVs 404 are volumes in which glass is removed and conductive materials are placed in the volumes, sufficient to enable electrical communication from an upper surface to a lower surface. As illustrated in embodiment of the layer of glass 402, the TGVs 404 are substantially perpendicular to an upper surface of the layer of glass 402. In embodiments that manufacture a panel at a time, the X length, and a corresponding Y length (defining an area in a top down or plan view) may be in a range of a first length (e.g., X) in a range of 10 millimeters to 500 millimeters, and a second length (e.g., Y) in a range of 10 millimeters to 500 millimeters, the first length perpendicular to the second length.

Embodiment 400 depicts the glass core 204/402 having through-glass vias 404 created therein and having cavity 406 formed in the upper surface of the glass core or layer of glass 402. The figures reflect cross-sectional views, in which the portion for the cavity is depicted as a width from left to right on the page; however, in a top-down view, the portion for the cavity would appear as an area. The TGVs 404 and the cavity 406 are created in the glass core or layer of glass 204/402 by removing an amount of glass material. The TGVs 404 and cavity 406 may be created with a wet etch and followed by laser drilling or ablation. TGV sidewalls and cavity walls are substantially straight (i.e., 90 degrees from perpendicular to an upper surface of the glass core or layer of glass 204/402, plus or minus 20 degrees; however, in other embodiments, the cavity walls may be 90 degrees plus or minus 10 degrees) and may have an internal taper reflecting the drill or ablation process used to open the cavity.

At 804, embodiment 410 illustrates applying copper metallization to fill up the TGV holes and to form copper pads on an upper surface and on a lower surface of the layer of glass 402. Also at 804, embodiment 415 illustrates applying solder resist or a polyimide film lamination followed by a hot press to conform the film to the cavity.

At 806, a temporary carrier 426 may be removably attached and the embodiment flipped. In some scenarios a double-sided fabrication process is performed, as illustrated with embodiment 420, in which two different glass cores are flipped and removably attached to the temporary carrier 426. A first glass core 422 is attached at its upper surface to one side of the temporary carrier 426 and a second glass core 424 is attached at its upper surface to the opposite surface of the temporary carrier 426. Respective cavities 406 may be filled with a sacrificial material 428 such as a polymer. Some examples of the sacrificial material include polyaldehydes, polyolefin sulfones, and polycarbamates.

With reference to FIG. 5, at 808, an organic build-up layer 502/504 is created on the lower surface of the glass core 422 and 424 respectively. The organic build-up layers include one or more dielectric layers with redistribution layers (RDL) conductive traces patterned therein, as is known in the art. The dielectric layers can be a suitable dielectric as described above. The conductive material used for conductive contacts, HB contacts, and RDL traces and vias may comprise a metal (e.g., copper, aluminum, nickel, cobalt, iron, tin, gold, silver, or combinations thereof) or another suitable conductive material.

Upon completion of the fabrication of the organic build-up layers, the glass core substrate 506 and glass core substrate 508 may be removed from the temporary carrier (at 808). In order to assemble the glass core substrate 508 with a stacked cache assembly of embodiment 330, the glass core substrate 506/508 may be flipped again and a glass carrier 602 may be removably attached to a lower surface of the organic buildup layer 504 of the glass core substrate 508, as shown in embodiment 600. In various embodiments, the solder bumps created at the top of the TGVs may be subjected to heat (reflow).

At 810, an underhung cache architecture or embodiment 330 is attached to the glass core substrate 508, as shown in embodiment 606. Attachment is via the microbumps to the upper surface of the glass core substrate 508, such that the underhung cache or stacked cache fits into the cavity formed in the upper surface of the glass core as described hereinabove. As illustrated with embodiment 608, at 812, the application of mold/underfill (MUF 610) around the stacked cache assembly or embodiment 330 on the upper surface of the glass core substrate 508 may be performed and the deposition of conductive contacts, such as solder balls 612 arranged in a ball grid array (BGA) may be performed, creating embodiment 608.

At 814, the embodiment 608 may be subjected to further assembly into a system package, such as being attached to a printed circuit board (PCB) or motherboard, having an encapsulant overlaid on it, having a power supply electrically coupled to it, and the like. Further, overmolding and thermal solutions (not shown) may be added.

The above embodiments may provide, in a multi-die package or multi-die assembly, the functionality conventionally associated with a monolithic system on chip (SoC). The above is not an exhaustive list of multi-die assemblies or systems that implement an underhung cache architecture. Those with skill in the art will appreciate that additional multi-die assembly embodiments, not illustrated, are supported based on figures and descriptions included herein. The following figures and description provide additional context for the cores, wafers, and assemblies described above.

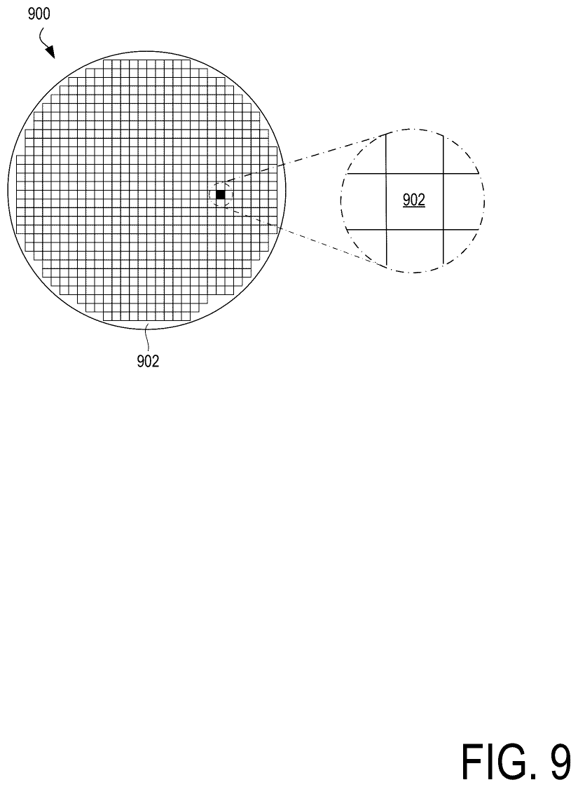

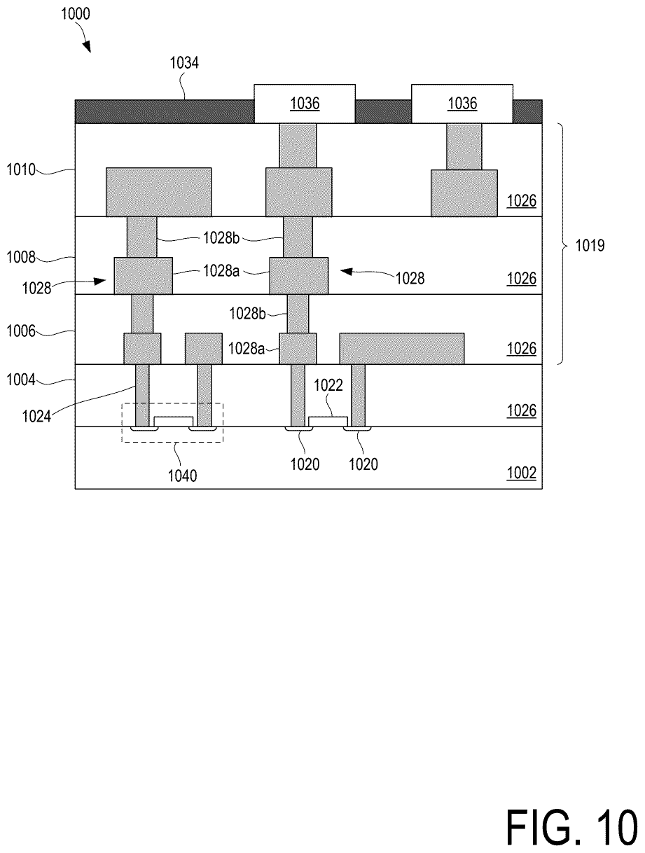

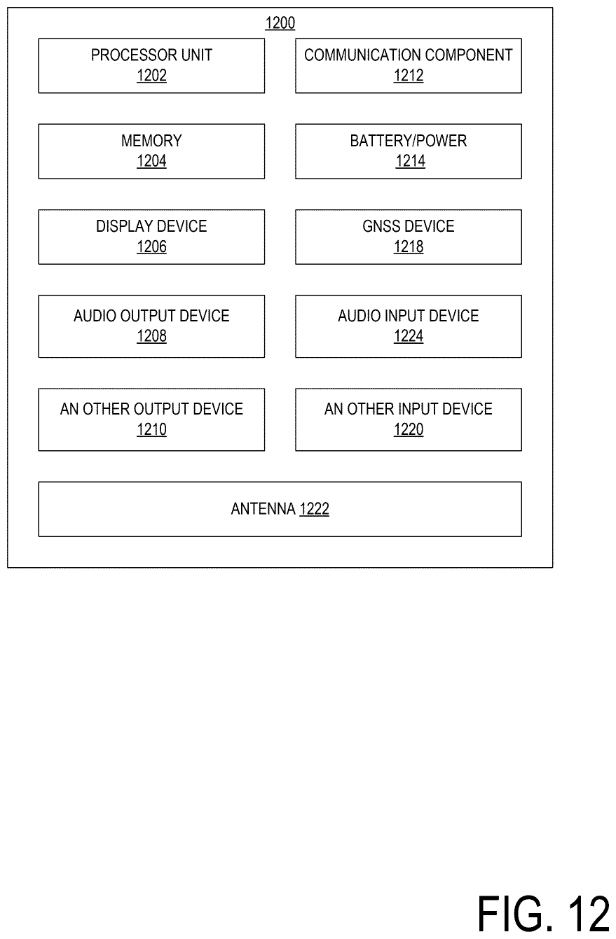

FIG. 9 is a top view of a wafer 900 and dies 902 that may be included in any of the embodiments disclosed herein. The wafer 900 may be composed of semiconductor material and may include one or more dies 902 formed on a surface of the wafer 900. After the fabrication of the integrated circuit components on the wafer 900 is complete, the wafer 900 may undergo a singulation process in which the dies 902 are separated from one another to provide discrete “chips” or destined for a packaged integrated circuit component. The individual dies 902, comprising an integrated circuit component, may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 902. For example, a memory array formed by multiple memory devices may be formed on a same die 902 as a processor unit (e.g., the processor unit 1202 of FIG. 12) or other logic that is configured to store information in the memory devices or execute instructions stored in the memory array. In some embodiments, a die 902 may be attached to a wafer 900 that includes other die, and the wafer 900 is subsequently singulated, this manufacturing procedure is referred to as a die-to-wafer assembly technique.

FIG. 10 is a cross-sectional side view of an integrated circuit 1000 that may be included in any of the embodiments disclosed herein. One or more of the integrated circuits 1000 may be included in one or more dies 902 (FIG. 9). The integrated circuit 1000 may be formed on a die substrate 1002 (e.g., the wafer 900 of FIG. 9) and may be included in a die (e.g., the die 902 of FIG. 9).

The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit 1000 may be used. The die substrate 1002 may be part of a singulated die (e.g., the dies 902 of FIG. 9) or a wafer (e.g., the wafer 900 of FIG. 9).

The integrated circuit 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020.

The gate 1022 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may comprise a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be conducted to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuits having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines of interconnect structures 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit 1000 with another component (e.g., a printed circuit board). The integrated circuit 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit 1000 is a double-sided die, the integrated circuit 1000 may include another metallization stack (not shown) on the opposite side of the device layer(s) 1004. This metallization stack may include multiple interconnect layers as discussed above with reference to the interconnect layers 1006-1010, to provide electrically conductive paths (e.g., including conductive lines and vias) between the device layer(s) 1004 and additional conductive contacts (not shown) on the opposite side of the integrated circuit 1000 from the conductive contacts 1036.

In other embodiments in which the integrated circuit 1000 is a double-sided die, the integrated circuit 1000 may include one or more through-silicon vias (TSVs) through the die substrate 1002; these TSVs may make contact with the device layer(s) 1004, and may provide electrically conductive paths between the device layer(s) 1004 and additional conductive contacts (not shown) on the opposite side of the integrated circuit 1000 from the conductive contacts 1036. In some embodiments, TSVs extending through the substrate can be used for routing power and ground signals from conductive contacts on the opposite side of the integrated circuit 1000 from the conductive contacts 1036 to the transistors 1040 and any other components integrated into the integrated circuit 1000 die, and the metallization stack 1019 can be used to route I/O signals from the conductive contacts 1036 to transistors 1040 and any other components integrated into the integrated circuit 1000 die.

Multiple integrated circuits 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

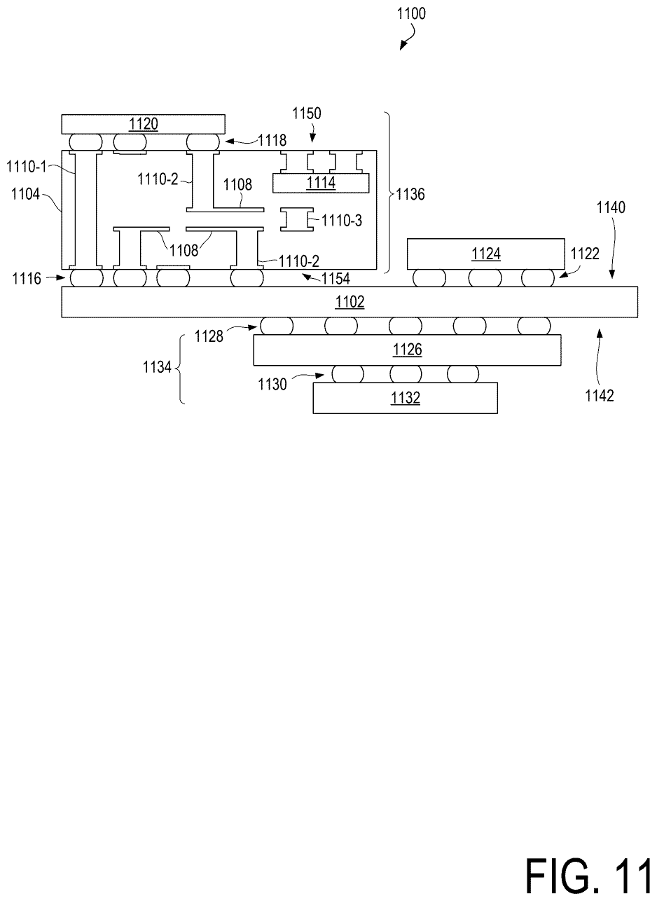

FIG. 11 is a cross-sectional side view of a microelectronic assembly 1100 that may include any of the embodiments disclosed herein. The microelectronic assembly 1100 includes multiple integrated circuit components disposed on a circuit board 1102 (which may be a motherboard, system board, mainboard, etc.). The microelectronic assembly 1100 may include components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The microelectronic assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpackaged integrated circuit component that includes one or more integrated circuit dies (e.g., the die 902 of FIG. 9, the integrated circuit 1000 of FIG. 10) and/or one or more other suitable components.

The unpackaged integrated circuit component 1120 comprises solder bumps attached to contacts on the die. The solder bumps allow the die to be directly attached to the interposer 1104. In embodiments where the integrated circuit component 1120 comprises multiple integrated circuit die, the dies can be of the same type (a homogeneous multi-die integrated circuit component) or of two or more different types (a heterogeneous multi-die integrated circuit component). In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through-silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The integrated circuit assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the embodiments disclosed herein. For example, any suitable ones of the components of the electrical device 1200 may include one or more of the microelectronic assemblies 1100, integrated circuit components 1120, integrated circuits 1000, integrated circuit dies 902, or structures disclosed herein. A number of components are illustrated in FIG. 12 as included in the electrical device 1200, but any one or more of these components may be omitted or duplicated, as suitable for the application. In some embodiments, some or all the components included in the electrical device 1200 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1200 can comprise one or more processor units 1202 that are heterogeneous or asymmetric to another processor unit 1202 in the electrical device 1200. There can be a variety of differences between the processor units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, the term “electronic component” can refer to an active electronic circuit (e.g., processing unit, memory, storage device, FET) or a passive electronic circuit (e.g., resistor, inductor, capacitor).

As used herein, the term and “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die; the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is an apparatus, comprising: a first die comprising an integrated circuit and a first static random-access memory (SRAM) component; wherein the first die has a lower surface defined by a plurality of solder bumps located below the integrated circuit, and a first insulating material with a plurality of first conductive contacts therein located below the first SRAM component; a second die comprising a second SRAM component and an upper surface comprising a second insulating material with a respective plurality of second conductive contacts therein; the second die is positioned on the first SRAM component and physically coupled thereto, such that the plurality of the first conductive contacts is directly attached to the respective plurality of the second conductive contacts, and the first insulating material is directly attached to the second insulating material.
Example 2 includes the subject matter of Example 1, wherein the first insulating material and the second insulating material comprise a dielectric material.
Example 3 includes the subject matter of Example 1, wherein the first conductive contacts and the second conductive contacts comprise a metal.
Example 4 includes the subject matter of Example 1, wherein the first conductive contacts and the second conductive contacts comprise copper.
Example 5 includes the subject matter of Example 1, wherein the first conductive contacts and the second conductive contacts are to route control and data lines from the first die to the second die.
Example 6 includes the subject matter of any one of Examples 1-5, wherein the integrated circuit is a central processing unit (CPU) or a graphics processing unit (GPU).
Example 7 includes the subject matter of any one of Examples 1-6, wherein the first die further comprises at least one additional integrated circuit component.
Example 8 includes the subject matter of any one of Examples 1-7, further comprising: a layer of glass having multiple through-glass vias; the layer of glass attached to the lower surface of the first die, wherein individual solder bumps on the first die are electrically coupled to a conductive material in a respective through-glass via; and wherein the layer of glass further has a cavity formed in an upper surface of the layer of glass; and wherein the cavity accommodates the second die.
Example 9 is a multi-die assembly, comprising: a cache chiplet comprising: a first die comprising an integrated circuit and a first static random-access memory (SRAM) component; wherein the first die has a lower surface defined by a plurality of solder bumps located below the integrated circuit, and a first insulating material with a plurality of first conductive contacts therein located below the first SRAM component; a second die comprising a second SRAM component and an upper surface comprising a second insulating material with a respective plurality of second conductive contacts therein; the second die is positioned on the first SRAM component and physically coupled thereto, such that the plurality of the first conductive contacts is directly attached to the respective plurality of the second conductive contacts, and the first insulating material is directly attached to the second insulating material; and a layer of glass having multiple through-glass vias and a cavity formed in an upper surface of the layer of glass; the cache chiplet attached to the layer of glass; wherein individual solder bumps on the first die are electrically coupled to a conductive material in a respective through-glass via; and wherein the cavity accommodates the second die.
Example 10 includes the subject matter of Example 9, further comprising an organic build layer on a lower surface of the layer of glass, the organic build layer comprising a dielectric material with one or more conductive traces therein.
Example 11 includes the subject matter of Example 10, further comprising: a plurality of solder balls on a lower surface of the organic build layer; and at least one electrical path from the first die to a solder ball.
Example 12 includes the subject matter of Example 11, further comprising a printed circuit board attached to the plurality of solder balls.
Example 13 includes the subject matter of any one of Examples 9-12, wherein the layer of glass has a thickness in a range of 20 microns +/−5 microns to 1.5 millimeters +/−5 microns.
Example 14 includes the subject matter of any one of Examples 9-12, further comprising a mold and underfill material surrounding the first die on the upper surface of the layer of glass.
Example 15 includes the subject matter of any one of Examples 9-14, wherein the first die further comprises at least one additional integrated circuit component.
Example 16 is a method, comprising: selecting a first die comprising an integrated circuit and a first cache component; wherein the first die has a lower surface defined by a plurality of solder bumps located below the integrated circuit, and a first insulating material with a plurality of first conductive contacts therein located below the first cache component; selecting a second die comprising a second cache component and an upper surface comprising a second insulating material with a respective plurality of second conductive contacts therein; and hybrid bonding the second cache component on the first cache component, thereby creating a cache stacked side of the first die.
Example 17 includes the subject matter of Example 16, further comprising: depositing a seed layer on the stacked side of the first die; patterning the seed layer with photoresist; exposing the photoresist; and depositing copper over the exposed photoresist.
Example 18 includes the subject matter of Example 17 removing the photoresist and plating the copper with solder, thereby creating solder bumps.
Example 19 includes the subject matter of Example 18, further comprising: forming a glass substrate with a cavity in an upper surface; the glass substrate further comprising a plurality of through glass vias; and attaching the cache stacked side of the first die to the glass substrate by positioning the second cache component in the cavity and electrically coupling individual solder bumps to conductive material in a respective through glass via.
Example 20 includes the subject matter of Example 19, further comprising creating an organic build-up layer on a lower surface of the glass substrate.

What is claimed is:

1. An apparatus, comprising:
a first die comprising an integrated circuit and a first static random-access memory (SRAM) component;
wherein the first die has a lower surface defined by a plurality of solder bumps located below the integrated circuit, and a first insulating material with a plurality of first conductive contacts therein located below the first SRAM component;
a second die comprising a second SRAM component and an upper surface comprising a second insulating material with a respective plurality of second conductive contacts therein;
the second die is positioned on the first SRAM component and physically coupled thereto, such that the plurality of the first conductive contacts is directly attached to the respective plurality of the second conductive contacts, and the first insulating material is directly attached to the second insulating material.

2. The apparatus of claim 1, wherein the first insulating material and the second insulating material comprise a dielectric material.

3. The apparatus of claim 1, wherein the first conductive contacts and the second conductive contacts comprise a metal.

4. The apparatus of claim 1, wherein the first conductive contacts and the second conductive contacts comprise copper.

5. The apparatus of claim 1, wherein the first conductive contacts and the second conductive contacts are to route control and data lines from the first die to the second die.

6. The apparatus of claim 1, wherein the integrated circuit is a central processing unit (CPU) or a graphics processing unit (GPU).

7. The apparatus of claim 1, wherein the first die further comprises at least one additional integrated circuit component.

8. The apparatus of claim 1, further comprising:
a layer of glass having multiple through-glass vias;
the layer of glass attached to the lower surface of the first die, wherein individual solder bumps on the first die are electrically coupled to a conductive material in a respective through-glass via; and
wherein the layer of glass further has a cavity formed in an upper surface of the layer of glass; and
wherein the cavity accommodates the second die.

9. A multi-die assembly, comprising:
a cache chiplet comprising:
a first die comprising an integrated circuit and a first static random-access memory (SRAM) component;
wherein the first die has a lower surface defined by a plurality of solder bumps located below the integrated circuit, and a first insulating material with a plurality of first conductive contacts therein located below the first SRAM component;
a second die comprising a second SRAM component and an upper surface comprising a second insulating material with a respective plurality of second conductive contacts therein;
the second die is positioned on the first SRAM component and physically coupled thereto, such that the plurality of the first conductive contacts is directly attached to the respective plurality of the second conductive contacts, and the first insulating material is directly attached to the second insulating material; and
a layer of glass having multiple through-glass vias and a cavity formed in an upper surface of the layer of glass;
the cache chiplet attached to the layer of glass;
wherein individual solder bumps on the first die are electrically coupled to a conductive material in a respective through-glass via; and
wherein the cavity accommodates the second die.

10. The multi-die assembly of claim 9, further comprising an organic build layer on a lower surface of the layer of glass, the organic build layer comprising a dielectric material with one or more conductive traces therein.

11. The multi-die assembly of claim 10, further comprising:
a plurality of solder balls on a lower surface of the organic build layer; and
at least one electrical path from the first die to a solder ball.

12. The multi-die assembly of claim 11, further comprising a printed circuit board attached to the plurality of solder balls.

13. The multi-die assembly of claim 9, wherein the layer of glass has a thickness in a range of 20 microns +/−5 microns to 1.5 millimeters +/−5 microns.

14. The multi-die assembly of claim 9, further comprising a mold and underfill material surrounding the first die on the upper surface of the layer of glass.

15. The multi-die assembly of claim 9, wherein the first die further comprises at least one additional integrated circuit component.

16. A method, comprising:
selecting a first die comprising an integrated circuit and a first cache component;
wherein the first die has a lower surface defined by a plurality of solder bumps located below the integrated circuit, and a first insulating material with a plurality of first conductive contacts therein located below the first cache component;
selecting a second die comprising a second cache component and an upper surface comprising a second insulating material with a respective plurality of second conductive contacts therein; and
hybrid bonding the second cache component on the first cache component, thereby creating a cache stacked side of the first die.

17. The method of claim 16, further comprising:
depositing a seed layer on the stacked side of the first die;
patterning the seed layer with photoresist;
exposing the photoresist; and
depositing copper over the exposed photoresist.

18. The method of claim 17 removing the photoresist and plating the copper with solder, thereby creating solder bumps.

19. The method of claim 18, further comprising:
forming a glass substrate with a cavity in an upper surface;
the glass substrate further comprising a plurality of through glass vias; and
attaching the cache stacked side of the first die to the glass substrate by positioning the second cache component in the cavity and electrically coupling individual solder bumps to conductive material in a respective through glass via.

20. The method of claim 19, further comprising creating an organic build-up layer on a lower surface of the glass substrate.
